(19) United States
(12) Patent Application Publication
(10) Pub. No.: US 2004/0266184 A1
(43) Pub. Date: Dec. 30, 2004

(54) Post-deposition modification of interlayer dielectrics

(76) Inventors: Vijayakumar S. RamachandraRao, Hillsboro, OR (US); Kevin P. O'brien, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/609,963

(22) Filed: Jun. 30, 2003

(51) Int. Cl. H01L 21/302; H01L 21/461

(52) U.S. Cl. 438/689

(57) ABSTRACT

A method for modifying an interlayer dielectric (ILD) is disclosed. In one embodiment, an ILD is formed having metallization therein, which may have a protective layer. The ILD is then exposed to a first solution comprising a F⁻ ion, either aqueous with a co-solvent or an organic-HF in conjunction with an organic solvent in supercritical carbon dioxide. After exposing the ILD to the first solution, the ILD is exposed to a second solution comprising a silane in supercritical carbon dioxide. In another embodiment, the ILD is exposed to the first solution after a damascene process including a chemical mechanical polishing is performed on the ILD. In a further embodiment, the ILD can be polymerized to create an organic polymer network after the ILD has been exposed to the second solution.

### BACKGROUND OF THE INVENTION

An integrated circuit (IC) typically comprises numerous semiconductor devices formed on a single crystal silicon substrate. The semiconductor devices can be transistors, diodes, etc. The semiconductor devices must be connected with each other using conductive lines for the IC to function. The conductive lines are effectively metal wires that allow electrical communication between the semiconductor devices. Newer ICs, and especially microprocessors, are becoming increasingly complex. Because of the increasing number of semiconductor devices found in newer ICs, the number of conductive lines needed to connect the devices is also increasing. For complex ICs, a single layer of conductive lines is insufficient. As a result, the conductive lines must be layered upon one another to create layers of metallization. In order to isolate the conductive lines an interlayer dielectric (ILD) is used. The ILD is an insulating layer, such as silicon dioxide (SiO₂), which prevents shorts and unwanted communication between the conductive lines.

One way to fabricate layers of metallization for an IC involves using what is known as a damascene process. The first procedure of a damascene process is to deposit an ILD. An ILD is deposited either directly on a substrate, or on top of another existing layer of metallization. Once the ILD is deposited, portions of the ILD may be etched away to form recessed features, such as trenches and vias, which will accommodate the conductive lines. A trench can be created to accommodate an interconnect, which can connect different regions of the IC. A via can be created to accommodate either a via or a contact which will allow for communication between the interconnects of other layers or directly with the semiconductor devices in the substrate. A damascene process which creates either only trenches or vias is known as a single damascene process. A damascene process which creates both trenches and vias at once is known as a dual damascene process. In a dual damascene process, trenches and vias are created together.

After the recessed features are created, metal, such as copper or aluminum, is deposited in them to create the conductive lines. The deposition process typically deposits excess metal, which overfills the trenches and covers the entire surface of the ILD. The excess metal can be removed using a chemical mechanical polishing (CMP) process. The CMP process involves introducing a chemical slurry to the surface of the ILD while using a rotating polishing pad to remove excess metal and planarize the surface of the ILD.

Because feature sizes in ICs have recently become so small, the conductive lines in the layers of metallization are now separated by increasingly smaller gaps. An ILD comprises a dielectric material, which has a tendency to store charge, and can cause problems such as crosstalk and capacitive coupling between the conductive lines. A typical material used for ILDs is silicon dioxide (SiO₂). Silicon dioxide has a dielectric constant (k) of approximately 4.0. With the reduction in feature size and subsequent reduction in distance between conductive lines, it has become desirable to use low-k dielectrics to reduce crosstalk and capacitive coupling. A low-k dielectric is typically defined as one that has a dielectric constant of less than that of SiO₂, or of less than 4.0. Examples of low-k dielectrics include fluorosilicate glass (FSG) and carbon doped oxides (CDO).

While low-k dielectrics can reduce the incidence of capacitive coupling, they create a new problem. Low-k dielectrics tend to be a mechanically weak, typically because they include pores or air pockets. Air pockets are created in a dielectric material in order to reduce the dielectric contestant because the dielectric constant of air is approximately 1.0. However, the removal of material in order to create pores within an ILD results in a structurally weaker material, which may be damaged during processing. For example, the CMP process can typically cause cracks, shorts, and other deformities in the ILD. Using a low-k ILD may ultimately reduce product yields because of damage caused during processing.

### BRIEF DESCRIPTION OF THE DRAWINGS

FIG. 1A illustrates a cross section of a layer of metallization.

FIG. 1B illustrates a metallization layer which has been modified according to an embodiment.

FIG. 1C illustrates an entire ILD having been modified according to one embodiment.

FIG. 2 illustrates an embodiment for modifying an ILD post deposition and patterning.

FIG. 3 illustrates an embodiment for post deposition modification of an ILD.

FIG. 4 illustrates a cross section of a completed IC including several layers of metallization.

FIG. 5 illustrates a chemical structure of a Si-based porous ILD.

### DETAILED DESCRIPTION

Described herein is a method for post deposition modification of interlayer dielectrics. In the following description numerous specific details are set forth. However, it is understood that embodiments may be practiced without these specific details. For example, well known equivalent materials may be substituted in place of those described herein, and similarly, well known equivalent techniques may be substituted in place of particular semiconductor processing techniques disclosed. In other instances, well known structures and techniques have not been shown in detail in order not to obscure the understanding of this description.

An ILD can be modified, and its dielectric constant lowered, through changes to its chemical structure. In one embodiment, an ILD can be modified after its full damascene patterning. An ILD, such as a CDO or another porous silicon-based dielectric similar to porous CDO, methyl silsesquioxane (MSQ), or hydrogen silsesquioxane (HSQ) based materials, can be deposited and processed to form metallization in the ILD. After metallization is formed, the dielectric constant of the ILD can be lowered by selective chemical modification of the ILD. The process of forming metallization typically imparts substantial mechanical and thermal stress to an ILD. By modifying the ILD after metallization is formed, a stronger ILD material having a higher dielectric constant (higher-k) before modification can be used to withstand the stress of metallization process. In another embodiment, an ILD can be modified after it has been deposited and before it is processed. In certain applications, it may be desirable to modify an ILD before damascene processing in order to obtain a more thorough chemical modification. In one embodiment, a deposited ILD is modified by first exposing the ILD to a solution comprising an F⁻ ion, and then to a silane or silazane solution. In another embodiment, both the F⁻ and silane or silazane solutions are dissolved in SCCO₂ prior to exposing them to the ILD. The SCCO₂ allows for greater diffusion into the ILD, which leads to an increased extent of reaction by thorough removal of the reaction products. In a further embodiment, the silane or silazane is polymerized after the ILD is chemically modified to increase its strength.

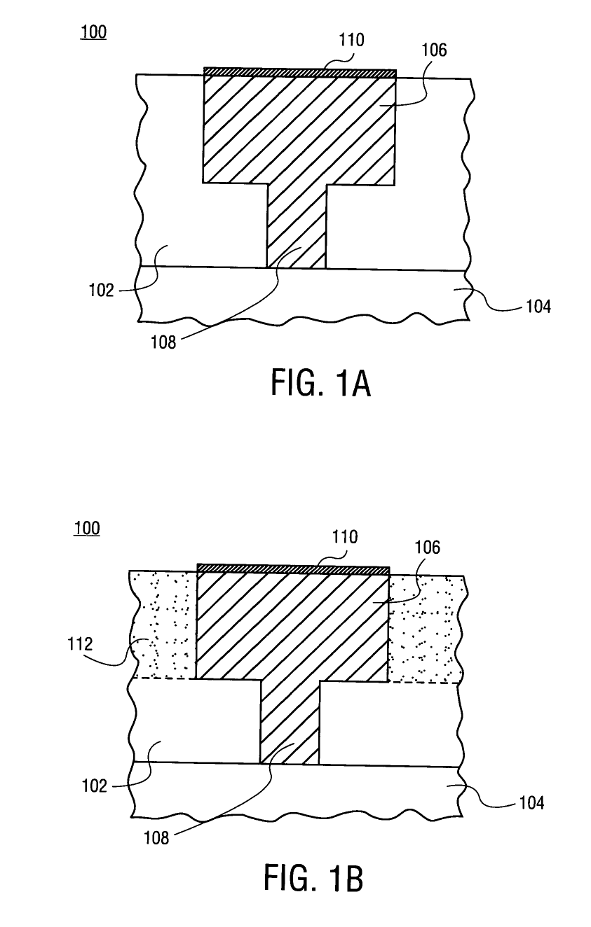

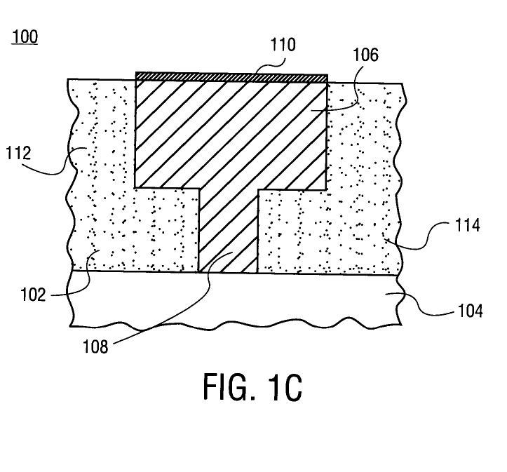

FIG. 1A illustrates a cross section of a layer of metallization. The layer of metallization 100 has been created using a dual damascene process. The layer of metallization 100 illustrates a typical interconnect and via, however, it is understood that any configuration of metallization will be appropriate. An ILD 102 may comprise any suitable ILD, including low-k ILDs such as CDO and FSG. The ILD 102 has been deposited on top of a layer 104 which may be another previously deposited and processed metallization layer or any other suitable substrate. The ILD 102 has formed in it a trench and a via. Metal, such as copper or aluminum, has been deposited in the trench and via to form an interconnect 106 and a via 108. The metal may be deposited in the recessed features using well-known processes such as electroplating and electroless deposition. Finally, a hermetic seal 110 has been deposited on top of the interconnect 106 to protect the interconnect 106 from the chemicals used during the modification of the ILD 102. The hermetic seal 110 may be a shunt comprising cobalt, tungsten, or other appropriate organic or inorganic materials that can remain in the metallization of structure or be removed later. The hermetic seal 110 may be deposited using well-known processes including chemical vapor deposition (CVD), physical vapor deposition (PVD), electroless deposition, etc.

The layer 100 described in FIG. 1A is a typical metallization layer as it appears after the completion of a dual damascene process. In one embodiment, the ILD 102 may be modified after the completion of the dual damascene process. The CMP portion of the damascene process can damage a weak, low-k ILD. If a relatively higher-k ILD were deposited and the damascene processing were performed on that ILD, the ILD 102 could be modified after the completion of the damascene process in order to lower its dielectric constant (k-value). This would create a metallization layer having a low-k ILD without subjecting a lower-k ILD to the additional thermal and mechanical stress of the damascene process. The ILD 102 may also be modified before the deposition of metal or before patterning of the ILD 102 if appropriate for the application.

FIG. 1B illustrates a metallization layer which has been modified according to an embodiment. As can be seen the portion of the ILD 102 that is trench height 112 has been modified after the completion of the damascene process, including deposition of metal and CMP. The hermetic seal or other shunt 110 has protected the metal interconnect 106 from the reactants which were used during the modification of the ILD 102. As will be discussed below, reactants having different reaction and diffusion rates can be selected to modify a certain depth of the ILD in a certain amount of time.

FIG. 1C illustrates an entire ILD having been modified according to one embodiment. Both the trench height portion 112 and the via height portion 114 have been modified. As above, the reactants used for the modification can be chosen so that the reaction and diffusion rates dictate how much of the ILD 102 is modified. The reactants can be introduced to the ILD 102 for a specific amount of time in order to insure that only the desired portion of the ILD 102 is modified. In one embodiment, it may only be desirable to modify the trench height portion 112 because the capacitive coupling is most severe between the interconnects, due to their closer proximity. However, depending on the application, any amount of modification may be necessary or desirable.

The ILD 102 as originally deposited may be a carbon doped oxide (CDO) or other spin-on Si-based low-k ILD. In general Si-based ILD's including CDO's are Si—O based networks with carbon atoms replacing some of the silcon and oxygen atoms. The silicon-carbon (Si—C) bonds that are created by doping the SiO₂ have a lower polarity than the silicon-oxygen (Si—O) bonds that comprise the SiO₂. Lower polarity bonds lower the dielectric constant of a dielectric material. Once the ILD 102 has been deposited or once the dual damascene process has been completed, the ILD 102 can be modified. The ILD 102 can be modified by individually introducing two reactants to it. First, a hydrogen fluoride (HF) or another solution that can provide an F⁻ ion, such as ammonium fluoride (NH₄F), organic fluorides having an adduct such as an organic solvent etc., may be introduced to the ILD 102. The F⁻ ion provided by this solution will attack the ILD structure and create pores, which contain air and therefore reduce the dielectric constant of the ILD. After introducing the F⁻ solution to the ILD 102, a silane solution including a silazane or a silane coupling agent may be introduced to the ILD 102. As used in this disclosure, the term silane solution may include silazane solutions or silane coupling agents. The silane solution will increase the number of Si—C bonds relative to the number of Si—O bonds. This will ultimately result in reduction of the dielectric constant of the ILD 102 because of the lower polarity of the Si—C bonds. Either of or both of the F⁻ solution or the silane solution may be dissolved in a supercritical fluid such as SCCO₂, with or without additional co-solvents, such as ethanol, iso-propyl alcohol (IPA) methanol, acetone, pyridine etc. The supercritical fluid has nearly zero viscosity and nearly zero surface tension and allows the reactants dissolved within it to better penetrate the ILD 102. This is due to the increased diffusion of SCCO₂, which is a result of the aforementioned properties. Ultimately, dissolution of the reactants in SCCO₂ can result in a lower dielectric constant. Once the processing by the F⁻ and silane compounds is complete, the ILD 102 can be polymerized to increase its strength. In order to polymerize the ILD 102 using the silane, an unsaturated silane should be used to create the polymers.

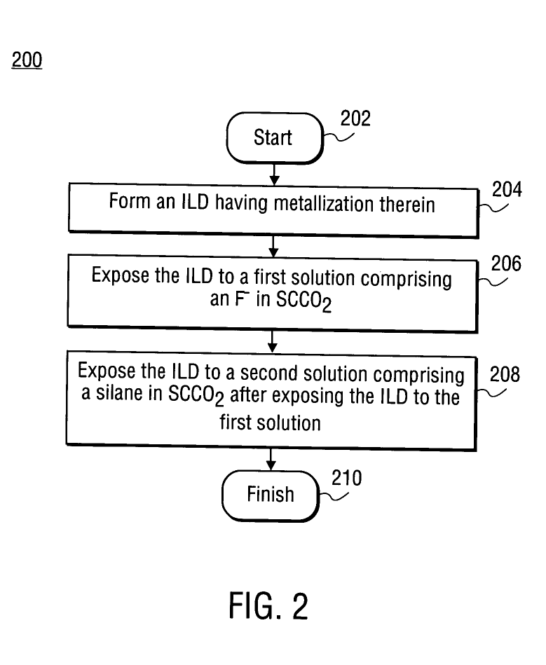

FIG. 2 illustrates an embodiment for modifying an ILD post deposition and patterning. The process 200 starts in start block 202. In block 204, an ILD is formed having a metallization therein. For example, the ILD may be formed using a damascene or dual damascene process to create interconnects and other conductive lines on the semiconductor. Also, the conductive lines may have been formed using subtractive processes, which deposit and then mask metal, and etch away unwanted metal. The ILD may be, for example, the ILD 102 as in FIG. 1A. In one embodiment, the ILD may be a CDO film, an SiO₂ film, an FSG film, or another appropriate dielectric material. In block 206 the ILD is exposed to a first solution comprising a F⁻ ion dissolved in SCCO₂. As above, the F⁻ ion may be provided by HF, NH₄F, etc. When the F⁻ ion is introduced to the ILD it attacks the structure of the ILD and creates pores within the structure. The pores are air pockets that reduce the dielectric constant of the ILD because air has a dielectric constant of approximately 1.0. The F⁻ solution that is introduced to the ILD should be either a mild aqueous solution or should be dissolved in an alcohol. The hydrolysis or the hydrogenation of the resulting Si—O bonds are required to form Si—OH for the subsequent step of silanation or silylation.

In block 208 the ILD is exposed to second solution comprising a silane in SCCO₂. After the pores have been created using the F⁻ compound, the silane alters the chemical structure of the ILD. A typical SiO₂ ILD consists of a lattice of Si—O—Si bonds and Si—OH bonds at the surface. The silane could be, for example, a silane coupling agent such as hexamethyldisilazane (HMDS), which has a structure containing six alkyl groups of CH₃. The silane-coupling agent reduces the number of Si—O bonds relative to the number of Si—C bonds. Because Si—C bonds are less polar than Si—O bonds, the dielectric constant of the ILD is reduced. Further, Si—C bonds occupy more space than Si—O bonds and therefore can also increase the strength of the ILD, which may have been weakened by the attack by the F⁻ ion.

The SCCO₂, because of its extremely low viscosity and surface tension, helps both solutions to increase their penetration into the ILD and ultimately helps to reduce the dielectric constant of the ILD. Further, the SCCO₂ is created at a relatively high pressure and high temperature. When the pressure on the ILD is released, the unreacted reactants can be easily removed from the ILD. However, it is understood that to the process of using an F⁻ compound and a silane compound to reduce the dielectric constant of an ILD may not require the use of SCCO₂, and in some instances it may be desirable to perform these processes without using SCCO₂ as a delivery vehicle, or using a combination of both liquid phase and supercritical phase.

Once the ILD has been exposed to the second solution in block 208, the process 200 moves on to the finish block 210 and the post processing of the ILD is complete. The ILD may be finished by optionally creating a partial organic polymer network by polymerizing the silane or the silazane using an appropriate unsaturated silane coupling. Polymerization of the silane or silazane can only occur with an unsaturated silane, so if polymerization is to be performed, an unsaturated silane should be used. Once the processing is complete, a new layer of metallization may be added on top of the ILD or the IC may be completed.

In alternate embodiments, an F⁻ or silane solution may be dissolved in SCCO₂ and introduced to an ILD individually, without introducing the other solution. The F⁻ and silane will retain their normal effects, while the diffusion of the reactants will increase because of the SCCO₂. This may be advantageous if a lower-k ILD is required, and a reduced number of processing procedures is wanted.

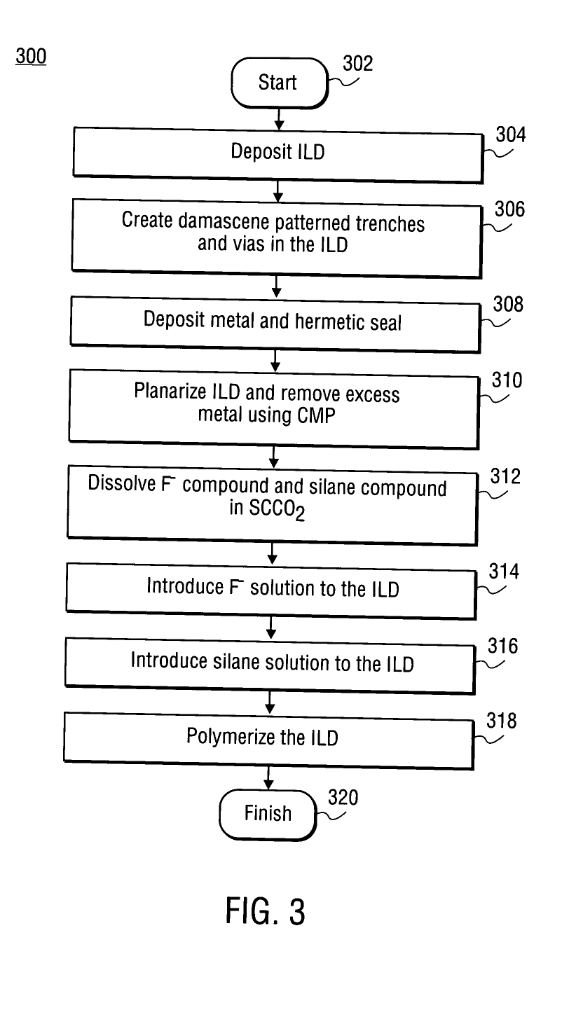

FIG. 3 illustrates an embodiment for post deposition modification of an ILD. The process 300 begins in start block 302. In block 304, an ILD, such as a silicon dioxide, CDO, FSG, or another porous low-k ILD may be deposited. The ILD may be deposited using chemical vapor deposition (CVD), spin-on techniques, or other appropriate processes. A porous CDO can work well as an ILD for back end of the line (BEOL) microprocessor processing. A porous CDO is a network of carbon, silicon, oxygen, and air. A CDO, for example, can have a dielectric constant of approximately 3.0. However, no production worthy techniques exist to lower the dielectric constant of the ILD into the 2.3 range. Using the process described here, a porous CDO having a dielectric constant of approximately 3.0 can be deposited, and can then be chemically modified to obtain an ultra low-k ILD using known production techniques.

Once the ILD has been deposited, the process continues to block 306 where damascene patterned trenches and vias are created in the ILD. In one embodiment, the ILD may contain either damascene patterned trenches or damascene patterned vias. In another embodiment, a dual damascene process may be performed on the ILD to create both trenches and vias.

In block 308, metal is deposited in the recessed features of the ILD. A tantalum (Ta), tantalum nitride (TaN), or other barrier layer may first be deposited to act as a diffusion barrier. Next, if an electroplating process is to be used, a copper or other seed layer may be deposited. The barrier and seed layers can be deposited using CVD, PVD, atomic layer deposition (ALD), etc. Finally, copper, aluminum, or another appropriate conductive material may be deposited in the trenches to form the conductive lines. The metal may be deposited using an electroplating process, an electroless plating process, or any other well-known deposition technique. After the metal has been deposited, metal will typically cover the top surface of the ILD, which will short the interconnects together. This top layer of metal needs to be removed and the ILD needs to be planarized in order to properly isolate the interconnects and allow for proper function of the layer of metallization. CMP is the process typically used to planarize an ILD. The CMP process typically involves introducing a chemical slurry onto the top surface of the ILD and using a rotating polishing pad to remove the excess metal and to planarize the surface of the ILD. The CMP process can create fractures and other damage within the ILD because of the thermal and mechanical stresses caused by the polishing pad. As a result, a mechanically weak low-k ILD will be easily damaged during a CMP process. Therefore, in one embodiment, it is desirable to perform the CMP before the ILD is exposed to the F⁻ and silane solutions. Since the CMP can be performed on a higher-k ILD before modification occurs, the damage can be limited because the higher-k ILD will be structurally stronger than a resulting modified lower-k ILD. However, the process may also be performed on an ILD before it is patterned or before metal is deposited. Once the interconnects are formed, a hermetic seal comprising tungsten, cobalt, or another appropriate material can be deposited on the interconnect to protect the metal from the F⁻ and silane solutions.

At block 312, an F⁻ compound and a silane compound are dissolved in a supercritical carbon dioxide (SCCO₂). The F⁻ ion may, as above, be provided by an HF, NH₄F, etc. solution. A supercritical fluid occurs at high temperature and pressure and has the properties of both a liquid and a gas. Although SCCO₂ is specifically mentioned here, other supercritical fluids, such as supercritical ethane or propane, or a mixture of variety a supercritical media may also be used. The SCCO₂ allows the F⁻ and silane solutions that are dissolved in it to better penetrate the structure of the ILD by increasing their diffusivity. The SCCO₂ is effectively a delivery system for the F⁻ and the silane solutions. This allows for more thorough modification of the ILD by removing the reaction products, and as a result, a lower dielectric constant. The SCCO₂ is also capable of dissolving a large quantity of reactants, which will effectively increase the reaction rate. Additionally, carbon dioxide interacts well with fluoride compounds and silicon, therefore insuring that a wide range of silanes and fluoride compounds will be soluble in SCCO₂. Aqueous HF can be dissolved in SCCO₂ using organic solvents such as isopropyl alcohol (IPA), acetone, other alcohols or ethers, or surfactants. However, it is understood that this process may be also performed using a mild aqueous HF or silane without first dissolving the solution in SCCO₂.

Further, as mentioned above, the supercritical fluid is produced at a high temperature and high pressure. For example, carbon dioxide becomes supercritical at 31° Centigrade and 76 bar. A typical processing stage when using a supercritical carbon dioxide may be performed at 60° Centigrade and 200 bar. The high pressure required to produce a supercritical fluid can be used to evacuate unreacted reactants. When the pressure required for the initial creation of the supercritical fluid is released after the chemical reaction is complete or at another time, the ILD will be evacuated and unused reactants will be removed from the ILD along with the carbon dioxide.

In block 314 the F⁻ solution is introduced to the ILD. Here, an F⁻ solution may be a mild acidic aqueous HF dissolved in SCCO₂, an aqueous HF, or an alkyl HF (an adduct) having some alkyl group in it dissolved in an appropriate organic solvent. The F⁻ must be coupled with some compound that can provide an OH⁻ or an H⁺ ion, which will be necessary for hydrolysis of the Si—O—Si bonds. When the F⁻ solution is introduced to the ILD, the F⁻ ion will attack the ILD structure and create pores in the ILD. The air in the pores has a very low dielectric constant, thereby reducing the effective of dielectric constant of the ILD. A typical silicon dioxide film will have many Si—O—Si bonds. The F⁻ ion will attack and break the Si—O bonds. This can be seen in the following equation (1):

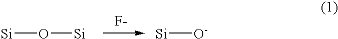

The Si—O—Si bonds have been attacked with the F⁻ ion and created Si—O⁻ bonds. The OH⁻ or just the H⁺ ion in the F⁻ solution now can combine with the Si—O bonds to hydrolyze the Si—O— bonds to create Si—OH bonds. This can be seen in the following equation (2):

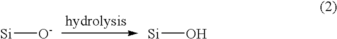

In block 316 the silane solution is introduced to the ILD. The use of F⁻ alone may not be sufficient to effectively lower the dielectric constant of the ILD. After the F⁻ has been introduced, the now very porous ILD may absorb water, which has a dielectric constant of approximately 78. Introducing silane to the ILD in addition to introducing F⁻ to the ILD can prevent the ILD from absorbing water by creating larger Si—C bonds. These bonds will also increase the strength of the ILD and by occupying some of the pores.

Silanes and silane coupling agents are highly reactive agents that readily form Si—C bonds. Therefore, the silane solution effectively increases the number of Si—C bonds relative to the number of more polar Si—O bonds. The effective reduction in the polarity of the ILD reduces the overall dielectric constant of the ILD. Further, the Si—C bonds are physically larger than Si—O bonds and as a result can increase the strength of the ILD. The silane solution can be a silane, a silazane, or a silane coupling agent. Moreover, the solution could contain a mixture of one or more of a silane, a silazane, or a silane coupling agent. An example of a simple silane coupling agent is HMDS. When the silane is introduced to the ILD a silylation or silanization occurs. A silylation occurs when using a silane, and a silanization occurs when using a silazane. The Si—OH bond created above by the hydrolysis is changed to an Si—O—Si—R bond as can be seen in equation (3):

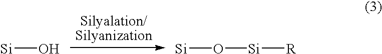

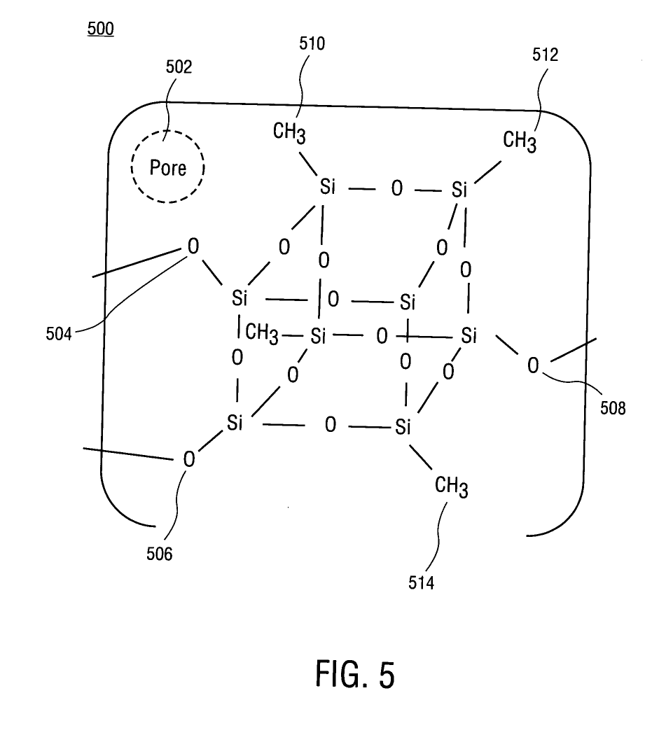

R can be an alkyl side group which leads to an Si—C bond. See FIG. 5 for an example of this chemical structure. R may be, for example, a CH₃⁻ group. This would lead to Si—O—Si—C bonds, therefore replacing the Si—O bond from equation (1) with an Si—C bond. The alkyl side group R will depend on the silane chosen. The R side group may also have a fluorine and a carbon that can further reduce the dielectric constant.

The choice of reactants and delivery mechanisms is important. The reaction rate of the reactants must be balanced with the diffusion rate of the delivery mechanism in order to maximize the modification of the ILD. For example, if a species diffuses more quickly than it reacts, the yield rate will be much lower because a large portion of the ILD will remain unreacted.

In block 318 the ILD may be polymerized to increase the strength of the ILD. This optional operation may be performed depending on the requirements of the application. The ILD can be polymerized using the R side group as shown in equation (3). If a carbon side group is used for the side group R, the side group R can have unsaturated bonds to create an organic polymer network. In one embodiment, R can be a side group that has a double bond such as —CH═CH₂ or a vinyl group. In order to polymerize the ILD, an initiator such as benzoyle peroxide (BPL) or azobisisobutyronitrile (AiBN) may be introduced into the ILD. The initiator will start the polymerization and the resulting partial organic polymer network will mechanically strengthen the ILD. The strengthening of the ILD can also eliminate the need for a hard mask, therefore reducing the amount of processing necessary after the aforementioned modification of the ILD.

In block 320 the modification of the ILD is complete. A low-k ILD has been created after the completion of damascene processing including CMP. However, it is understood that not all of the above procedures are required or necessary. For example, in one embodiment, an ILD may be exposed to the F⁻ and silane solutions prior to patterning. In another embodiment, an ILD may be modified by introducing aqueous an F⁻ ion and silane to it without using dissolving the reactants in supercritical fluids. In a further embodiment, the ILD may be modified after the trenches and vias are created in damascene processes and before any metal is deposited.

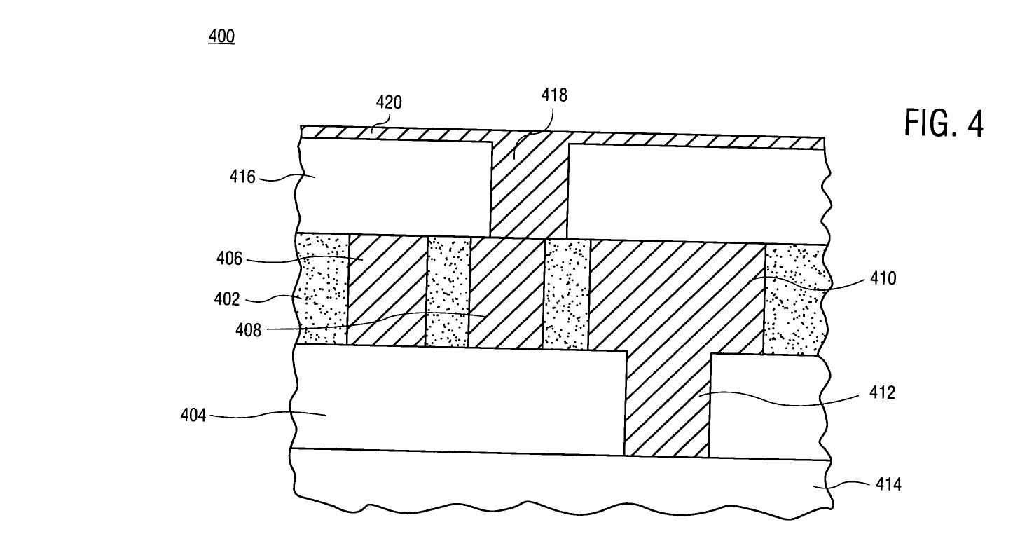

FIG. 4 illustrates a cross section of a completed IC including several layers of metallization. In the IC 400, the layer containing an ILD 402 has been partially modified. The trench height portion of the ILD 402 has been modified using the processes 200 or 300. The via height portion of the ILD 404 has not been modified. It may typically be more useful to modify the portions of the ILD which contain interconnects rather than vias because interconnects tend to be closer together, which can lead to or exacerbate capacitive coupling and crosstalk. Interconnects 406, 408, and 410 are in the modified portion of the ILD 402. The via 412 is in the unmodified portion of the ILD 404. The lower layer 414 may or may not have been modified. Further, the lower layer 414 may also be a substrate containing semiconductor devices. The upper layer 416 containing a via 418 has also not been modified. The interconnect 420 is an interconnect in a higher level and may or may not include a modified ILD. As can be seen from this illustration, the modification described herein may be done selectively, only on certain ILDs and certain portions of ILDs in an IC, as is needed to effectively reduce the dielectric constant and the incidence of capacitive coupling and crosstalk.

FIG. 5 illustrates a chemical structure of a Si-based porous ILD. The ILD shown in FIG. 5 may have began as an SiO₂ film, a CDO, or an MSQ-based porous Si-based dielectric. The chemical structure 500 is an exemplary drawing, and it is understood that many different chemical structures could result because of the modifications. The chemical structure 500 is representative of some of the individual physical and chemical modifications that may occur. For example, the pore 502 was created by the introduction of F⁻ to the ILD. The Si—O bonds 504, 506, and 508 are the unmodified bonds from the original SiO₂ or CDO ILD. The Si—C bonds 510, 512, and 514 may have been created during the doping of a CDO, or the may have been created by the reaction caused by the silane solution explained above being introduced to the ILD.

Damascene processing can easily damage low-k ILDs. Therefore it may be desirable to use a higher-k ILD during the damascene processing and modify the ILD after the damascene processing complete. However, it may also be useful to chemically modify an ILD before damascene processing has begun. An ILD can be modified by first introducing to it a solution that can provide an F⁻ ion, and then in a separate, subsequent process introducing a silane solution to it. Further, the diffusion of the F⁻ and silane compounds can be improved by dissolving them in a supercritical fluid, such as supercritical carbon dioxide, before they are introduced to the ILD. The F⁻ ion will attack the physical of the structure of the ILD and effectively reduce the dielectric constant of the ILD by removing material and creating air pockets. The silane will increase the number of Si—C bond relative to the number of more polar Si—O bonds. These two processes will reduce the ILD's dielectric constant substantially. Further, the ILD may be strengthened by polymerizing the ILD and creating an organic polymer network in the ILD after introducing the F⁻ and silane compounds.

This invention has been described with reference to specific exemplary embodiments thereof. It will, however, be evident to persons having the benefit of this disclosure that various modifications and changes may be made to these embodiments without departing from the broader spirit and scope of the invention. The specification and drawings are, accordingly, to be regarded in an illustrative rather than a restrictive sense.

What is claimed is:

1. A method, comprising:
forming an interlayer dielectric (ILD) having metallization formed therein;
exposing the ILD to a first solution comprising an F⁻ ion in supercritical carbon dioxide (SCCO₂); and
exposing the ILD to a second solution comprising a silane in SCCO₂ after exposing the ILD to the first solution.

2. The method of claim 1, wherein the ILD is exposed to the first solution after performing a damascene process including a chemical mechanical polishing (CMP) process.

3. The method of claim 1, further comprising:
polymerizing the ILD after exposing the ILD to the second solution.

4. The method of claim 1, wherein the ILD is chosen from a group consisting of carbon doped oxide (CDO), fluorosilicate glass (FSG), silicon dioxide (SiO₂), and a porous silicon-based dielectric.

5. The method of claim 2, wherein the metallization is formed in the ILD using a dual damascene process.

6. The method of claim 5, wherein only a trench portion of the ILD is exposed to the first and second solutions.

7. The method of claim 2, wherein the damascene process includes forming at least one interconnect, and:
depositing a hermetic seal on the at least one interconnect.

8. The method of claim 7, wherein the hermetic seal is chosen from a group consisting of cobalt, tungsten, and an organic material.

9. The method of claim 1, further comprising:
depressurizing the SCCO₂ to remove unreacted reactants.

10. The method of claim 1, wherein the SCCO₂ increases a diffusivity of the first and second solutions.

11. The method of claim 3, wherein polymerizing the ILD comprises polymerizing an unsaturated silane or silazane.

12. The method of claim 1, wherein the F⁻ ion is provided by a solution chosen form a group consisting of hydrogen fluoride (HF), ammonium fluoride (NSF), and organic fluorides.

13. A method, comprising:
forming an interlayer dielectric (ILD);
exposing the ILD to a solution comprising an F⁻ ion in supercritical carbon dioxide (SCCO₂).

14. The method of claim 13, further comprising:
exposing the ILD to a second solution comprising a silane in supercritical carbon dioxide (SCCO₂) after exposing the ILD to the solution.

15. The method of claim 13, further comprising:
forming at least one conductive line in the ILD before exposing the ILD to the solution.

16. The method of claim 13, wherein the F⁻ ion is provided by an acidic aqueous hydrogen fluoride (HF).

17. A method, comprising:
forming an interlayer dielectric (ILD);
exposing the ILD to a solution comprising a silane in a supercritical carbon dioxide (SCCO₂).

18. The method of claim 17, wherein the silane is hexamethyldisilazane (HMDS).

19. The method of claim 18, wherein the ILD has metallization formed therein.

20. A method, comprising:
depositing an interlayer dielectric (ILD);
introducing a first solution comprising an F⁻ ion to the ILD; and
introducing a silane solution to the ILD after introducing the first solution.

21. The method of claim 20, wherein the F⁻ ion is provided by an aqueous HF or organic fluoride in conjunction with an organic solvent dissolved in a supercritical carbon dioxide (SCCO₂).

22. The method of claim 20, wherein the silane solution comprises a silane dissolved in a supercritical carbon dioxide (SCCO₂).

23. The method of claim 20, further comprising:
polymerizing the ILD after introducing the silane solution.

24. The method of claim 20, wherein the F⁻ ion is introduced to the ILD after performing a damascene process including a chemical mechanical polishing (CMP) process.

25. A metallization layer fabricated by the method of:
forming an interlayer dielectric (ILD) having metallization therein;
exposing the ILD to a first solution comprising an F⁻ ion in supercritical carbon dioxide (SCCO₂); and
exposing the ILD to a second solution comprising a silane in SCCO₂ after exposing the ILD to the first solution.

26. The metallization layer of claim 25, wherein the method further comprises:
polymerizing the ILD after exposing the ILD to the second solution.

27. The metallization layer of claim 25, wherein the ILD is chosen from a group consisting of carbon doped oxide (CDO), fluorosilicate glass (FSG), silicon dioxide (SiO₂) and porous or non-porous spin-on silicon-based dielectrics.

28. A method, comprising:
depositing an interlayer dielectric (ILD);
exposing the ILD to a solution comprising silane; and
polymerizing the ILD after exposing the ILD to the solution.

29. The method of claim 28, wherein polymerizing further comprises:
introducing an initiator to the ILD.

30. The method of claim 29, wherein the initiator is selected from a group consisting of benzoyle peroxide (BPO) and azobisisobutyronitrile (AiBN).
